(19) United States
(12) Patent Application Publication
(10) Pub. No.: US 2024/0126936 A1
(43) Pub. Date: Apr. 18, 2024

(54) MULTI-SCALE AGGREGATION PATTERN ANALYSIS METHOD FOR COMPLEX TRAFFIC NETWORK

(71) Applicants: NORTH CHINA INSTITUTE OF AEROSPACE ENGINEERING, Langfang, Hebei (CN); ANHUI KELI INFORMATION INDUSTRY CO, LTD, Hefei, Anhui (CN)

(72) Inventors: Xia Zhu, Hebei (CN); Yingying Pei, Hebei (CN); Yongtao Jin, Hebei (CN); Guohong Li, Hebei (CN); Yulong Hao, Hebei (CN); Yuanping Liu, Hebei (CN); Yuyan Liu, Hebei (CN); Longfang Duan, Hebei (CN); Cui Jia, Hebei (CN); Qiyue Liu, Hebei (CN); Tao Ma, Hebei (CN); Shan An, Hebei (CN); Jia Xi, Hebei (CN); Zhihong Song, Anhui (CN)

(21) Appl. No.: 18/275,728

(22) PCT Filed: Jan. 5, 2023
(86) PCT No.: PCT/CN2023/070582

§ 371 Date: Aug. 3, 2023

(30) Foreign Application Priority Data
Jan. 7, 2022 (CN) 202210015815.1

(51) Int. Cl. G06F 30/13

(52) U.S. Cl. CPC G06F 30/13

(57) ABSTRACT

A multi-scale aggregation pattern analysis method for a complex traffic network is provided, which belongs to the field of the highway traffic network. Firstly, an adjacency matrix, a position attribute matrix, a distance weight matrix, a road grade matrix, and a time-phased traffic congestion degree matrix of a highway traffic network are calculated; secondly, a weight influence factor of the road network is incorporated based on a PageRank algorithm to determine order of critical nodes; finally, a two-dimensional decision diagram is drawn by two indicators: order of critical nodes and a shortest path distance. A new weighting matrix which accords with the actual situation of the road network is obtained by incorporating a position weight matrix, a distance weight matrix, a road grade weight matrix and a dynamic traffic congestion degree weight matrix based on a similarity matrix of the spectral clustering.

### CROSS-REFERENCE TO RELATED APPLICATION

This patent application claims the priority of Chinese Patent Application No. 202210015815.1 filed with China National Intellectual Property Administration on Jan. 7, 2022 and entitled “MULTI-SCALE AGGREGATION PATTERN ANALYSIS METHOD FOR COMPLEX TRAFFIC NETWORK”, the disclosure of which is incorporated by reference herein in its entirety.

### TECHNICAL FIELD

The present disclosure relates to the technical field of a highway traffic network, and in particular, to a multi-scale aggregation pattern analysis method for a complex traffic network.

### BACKGROUND

The highway traffic network is an important infrastructure for serving the economy, the society and the public, and is the backbone of the comprehensive transportation system. Analyzing the complex traffic network in multiple scales, mining functional blocks of the network structure, and identifying distribution characteristics of the geographic spatial network are important aspects of analyzing the highway traffic network.

At present, there are few studies on multi-scale analysis of the complex traffic network. Yang Pan et al. proposed that the scale is the basic feature of the objective world (Yang Pan. Multi-scale study on urban furniture color—with Hefei as an example [D]. Hefei University of Technology, 2019.), and the multi-scale study is an important means to understand the complex system of the objective world. The highway traffic network is complex and systematic. In order to obtain scientific and reasonable design strategies and principles for the highway traffic network, it is desirable to analyze the road network from multiple levels and perspectives. The multi-scale study undoubtedly provides a unique perspective for the road network analysis. Secondly, the existing studies on block aggregation characteristics of the highway traffic network are insufficient in data types. Zheng and Gao et al. studied the dynamic traffic information on the scale-free traffic network (Zheng J. F., Gao Z. Y. and Zhao et al. X. M., Properties of transportation dynamics on scale-free networks [J]. Phyicas A, 2007, 373(none): 837-844.), and found that congestion behavior has an impact on the traffic network. Adding weight influence factors such as dynamic traffic congestion degree to construct a road network theoretical model can provide more comprehensive theoretical support for traffic decision-making and service personnel. In addition, it is desirable to select a suitable clustering algorithm for the highway network aggregation pattern analysis. There are many algorithms for identifying modules in the complex network, such as a vertex clustering algorithm, a density-based algorithm, a random walk method, a circuit approximation method, and a spectral clustering algorithm. At present, the k-means clustering algorithm is mostly used to divide the aggregation blocks of the road network. However, the road network data is typical high-dimensional data, and using the k-means clustering algorithm to process high-dimensional data is not dominant, resulting in certain limitations in the study results.

### SUMMARY

An objective of some embodiments of the present disclosure is to provide a multi-scale aggregation pattern analysis method for the complex traffic network, which can analyze the block characteristics of the highway traffic network, obtain a result of the block aggregation characteristics of the highway traffic network across administrative divisions, and further provide decision-making reference for traffic planning, design work and maintenance work.

To achieve the above objective, the present disclosure provides the following technical solutions.

A multi-scale aggregation pattern analysis method for complex traffic network, including:
S1, calculating an adjacency matrix A, a position attribute matrix F, a distance weight matrix W, a road grade matrix L and a time-phased traffic congestion degree matrix T of a highway traffic network;
where:
(1) the adjacency matrix A=(aᵢⱼ)_{N×N} is a square matrix of order N, and an element aᵢⱼ on a i-th row and a j-th column is defined as follows:

$${a}_{i j} = \{ \begin{matrix}{e}_{ij} , i \neq j \\ 0 , i = j\end{matrix} , 1 \leq i , j \leq N \qquad ( 1 - 1 )$$

if there is a road segment connection between a node i and a node j, eᵢⱼ=1; otherwise, eᵢⱼ=0;
(2) the position attribute matrix F is constructed by using POI points to define a 500-meter buffer zone, and determining road segments in the highway traffic network covered by the buffer zone so as to set position attribute values of the road segments, weights of road segments in the buffer zone are set to 1, and weights of other road segments of the highway traffic network are set to 0;
assuming that vᵢ=1 (1≤i≤N) represents a position attribute of a road segment i according to a studied problem or an actual situation of the highway traffic network, and vᵢ=0 represents other situations, the position attribute matrix F is constructed as follows:

F=(v₁,v₂, . . . ,v_{N})_{1×N} (1-2)
(3) the distance weight matrix W=(wᵢⱼ)_{i,j=1}^{N}, wᵢⱼ represents a reciprocal of a shortest path length between the node i and the node j;

$${w}_{ij} = \{ \begin{matrix}\frac{1}{{d}_{ij}} … i \neq j \\ 0 … i = j\end{matrix} , 1 \leq i , j \leq N \qquad ( 1 - 3 )$$

where dᵢⱼ is a shortest path length between the node i and the node j in an initial traffic network structure, with a unit of km;
(4) the road grade matrix L=(lᵢⱼ)_{i,j=1}^{N}, an element lᵢⱼ refers to a weight of a road grade between the node i and the node j, and as the road grade increases, the weight also increases;
(5) the time-phased traffic congestion degree matrix T=(tᵢⱼ)_{i,j=1}^{N}, an element tᵢⱼ represents a weight of a traffic congestion degree between the node i and the node j, and as the congestion degree increases, a road weight also increases;
S2, obtaining an improved PageRank algorithm by incorporating a weight influence factor based on an original PageRank algorithm, so as to determine order of critical nodes, where:
(1) a Google matrix of the PageRank, represented by G, is defined as:

$$G = α {A}^{*} + \frac{( 1 - α )}{N} {I}_{N \times N} \qquad ( 1 - 4 )$$

where A* is a transition matrix of the adjacency matrix A obtained from an original traffic network; α is a damping factor, generally α=0.85; N represents a number of nodes in the highway traffic network, and I_{N×N} is a unit matrix of order N;
(2) a new weighting matrix K is defined by using the position attribute matrix F, the distance weight matrix W, the road grade matrix L and the time-phased traffic congestion degree matrix T:

K=F+W+L+T=(k₁,k₂, . . . ,kⱼ, . . . ,k_{N}) (1-5)

where kⱼ represents a j-th column of the weighting matrix K;
(3) each column vector kⱼ of the weighting matrix K is normalized to obtain a standard matrix K_{N};
(4) a new matrix G* is constructed and obtained by replacing

$$\frac{( 1 - α )}{N} {I}_{N \times N}$$

with (1−α)K_{N}:

G*=αA*+(1−α)K_{N} (1-6)
according to Perron-Frobenius theorem, a main eigenvector X₁^{*}={g(1), g(2), . . . , g(N)}(λ=1) of G* is calculated by setting a eigenvalue of a eigenvector λ=1, to obtain grades of critical nodes; g(1), g(2), . . . , g(N) represent respective components of the main eigenvector X1^{*}, and a value of a component indicates an importance degree of a node, and as the value of the component increases, the importance degree of the node increases, and a criticality grade also increases;
S3, drawing a two-dimensional decision diagram by two indicators: order of critical nodes and a shortest path distance, to determine center points and a number k of clusters in a spectral clustering, obtaining a new weighting matrix which accords with an actual situation of the road network by incorporating a position weight matrix, a distance weight matrix, a road grade weight matrix and a dynamic traffic congestion degree weight matrix based on a similarity matrix of spectral clustering, and carrying out clustering analysis to obtain aggregation blocks of the road network.

Further, in the S3, the drawing a two-dimensional decision diagram by two indicators: order of critical nodess and a shortest path distance, to determine center points and a number k of clusters in a spectral clustering, so obtaining a new weighting matrix which accords with an actual situation of the road network by incorporating a position weight matrix, a distance weight matrix, a road grade weight matrix and a dynamic traffic congestion degree weight matrix based on a similarity matrix of spectral clustering, and carrying out clustering analysis to obtain aggregation blocks of the road network, includes:
(1) constructing the two-dimensional decision diagram to select clustering center points and determine a number of clusters;
where the clustering center points are selected by using a method of two-dimensional decision diagram, a number of the clustering center points is the number of clusters, the clustering center points are determined based on ρ and δ, where ρ is a horizontal axis and δ is a vertical axis:

γᵢ=ρᵢδᵢ,i∈I_{S} (1-7)

where ρᵢ represents a i-th component of the main eigenvector X₁^{*}, and is used to evaluate importance of the node i; δᵢ represents a shortest path length between the node i and a more critical node, which is a critical node whose component value is greater than a predetermined threshold, that is, δᵢ represents a shortest path length between the node i and each critical node; I_{S} represents a set of nodes in an area S; a sequence of comprehensive values {γᵢ}ᵢ₌₁^{N} is calculated, where γᵢ=ρᵢδᵢ, i∈I_{S} represents a comprehensive value of the node i; as a reference value of γ increases, a possibly of the node i being a clustering center increases; therefore, {γᵢ}ᵢ₌₁^{N} are sorted in a descending order and a plurality of data points are extracted from the front of the sorted {γᵢ}ᵢ₌₁^{N} to back as block centers, k nodes distributed on upper right of the decision diagram are selected as clustering centers, and k is a number of clusters;
(2) constructing the weighting matrix, and dividing the road network into aggregation blocks by the spectral clustering, including:
for n sample points X={x₁,x₂, . . . ,xₙ} and a number k of clusters,
1) calculating a similarity matrix S={sᵢⱼ|1≤i≤n, 1≤j≤n} of n*n;

$${S}_{ij} = {e}^{\frac{- {‖ {x}_{i} - {x}_{j} ‖}^{2}}{2 {σ}^{2}}} \qquad ( 1 - 8 )$$

where ∥xᵢ−xⱼ∥ represents a distance between two sample points, and a parameter σ defines a neighborhood width of a sample point, as a value of the σ increases, a similarity between the sample point and a far sample point away from the sample point increases, and as a value of the σ decreases, the similarity between the sample point and the far sample point decreases;
2) obtaining a new weighting matrix R which accords with the actual situation of the road network by incorporating the position weight matrix F, the distance weight matrix W, the road grade weight matrix L and the dynamic traffic congestion degree weight matrix T based on the similarity matrix S;

R=S+F+W+L+T (1-9)
3) calculating a degree matrix D, where dᵢ=Σⱼ₌₁ⁿ rᵢⱼ is a sum of elements in each row of the weighting matrix R, and D is an n*n diagonal matrix composed of dᵢ;
4) calculating a Laplace matrix L=D^{-1/2}LD^{-1/2}=D^{-1/2}(D−W)D^{-1/2};
5) calculating eigenvalues of the Laplacian matrix L and sorting the eigenvalues from small to large;
6) selecting center nodes based on the two-dimensional decision diagram, and obtaining the number k of clusters;
7) calculating eigenvectors u₁,u₂, . . . ,uₖ of first k eigenvalues of the Laplacian matrix L by using the first k eigenvalues;
8) forming a matrix U={u₁,u₂, . . . ,uₖ},U∈R^{n+k} by using the eigenvectors of the first k eigenvalues;
9) letting yᵢ∈R^{k} be an eigenvector of a i-th row of U, where i=1,2, . . . ,n;
10) for i=1,2, . . . ,n, sequentially unitizing yᵢ∈R^{k}, so that |yᵢ|=1;
11) grouping new sample points Y={y₁,y₂, . . . ,yₙ} into clusters C₁,C₂, . . . ,Cₖ by using a k-means algorithm;
12) obtaining clustering result clusters A₁,A₂, . . . ,Aₖ, where Aₖ={yᵢ|yᵢ∈Cₖ}, i∈n.

Further, in step S2, the expression of A* is as follows:

$${A}^{*} = {( {a}_{ij}^{*} )}_{i , j = 1}^{N} \qquad ( 1 - 10 )$$

$${a}_{ij}^{*} = \{ \begin{matrix}\frac{{a}_{ij}}{{\sum }_{i = 1}^{N} {a}_{ij}} & if {\sum }_{i = 1}^{N} {a}_{ij} \neq 0 \\ 0 & otherwise\end{matrix} \qquad ( 1 - 11 )$$

$$where :$$

$${a}_{ij} = \{ \begin{matrix}{e}_{ij} , & i \neq j \\ 0 , & i = j\end{matrix} , 1 \leq i , j \leq N \qquad ( 1 - 12 )$$

when eᵢⱼ=1, it means that a road segment connection between the node i and the node j; when eᵢⱼ=0 it means other cases.

According to specific embodiments provided by the present disclosure, the present disclosure discloses the following technical effects. In the multi-scale aggregation pattern analysis method for the complex traffic network provided by the present disclosure, firstly, a road network theoretical model which adds influence factors of a position attribute weight, a geographical distance weight, a road grade weight and a dynamic time-phased traffic congestion degree weight is constructed, which provides a theoretical model basis for subsequent study; then an improved PageRank (APA, Adapted PageRank) algorithm is proposed to obtain sorting of critical nodes in the highway traffic network, and the clustering center points and the number of clusters are determined by two indicators: the sorting of the critical nodes and the shortest path distance; further, a APA-spectral clustering algorithm is proposed, which can cross the limitation of administrative divisions, obtain division results of special common blocks in the highway traffic network, maintain connectivity between blocks, and improve the overall efficiency of the highway traffic network.

### BRIEF DESCRIPTION OF THE DRAWINGS

To describe the technical solutions in embodiments of the present disclosure or in the prior art more clearly, the accompanying drawings required in the embodiments are briefly described below. Apparently, the accompanying drawings in the following description show merely some embodiments of the present disclosure, and other drawings can be derived from these accompanying drawings by those of ordinary skill in the art without creative efforts.

FIG. 1 is a flowchart of a multi-scale aggregation pattern analysis method for a complex traffic network according to the present disclosure;

FIG. 2 is a schematic diagram of point distribution of a decision diagram according to an embodiment of the present disclosure;

FIG. 3 is a schematic diagram of decision value results of the decision diagram according to an embodiment of the present disclosure;

FIG. 4 is an application result diagram of the multi-scale aggregation pattern analysis method for the complex traffic network with Langfang City, China as an example.

### DETAILED DESCRIPTION OF THE EMBODIMENTS

The technical solutions in the embodiments of the present disclosure will be described below clearly and completely with reference to the accompanying drawings in the embodiments of the present disclosure. Apparently, the described embodiments are merely some rather than all of the embodiments of the present disclosure. All other embodiments obtained by those of ordinary skill in the art based on the embodiments of the present disclosure without creative efforts shall fall within the protection scope of the present disclosure.

An objective of some embodiments of the present disclosure is to provide a multi-scale aggregation pattern analysis method for the complex traffic network, which can analyze the block characteristics of the highway traffic network, obtain a result of the block aggregation characteristics of the highway traffic network across administrative divisions, and further provide decision-making reference for traffic planning, design and maintenance works.

To make the above-mentioned objective, features, and advantages of the present disclosure clearer and more comprehensible, the present disclosure will be further described in detail below in conjunction with the accompanying drawings and specific embodiments.

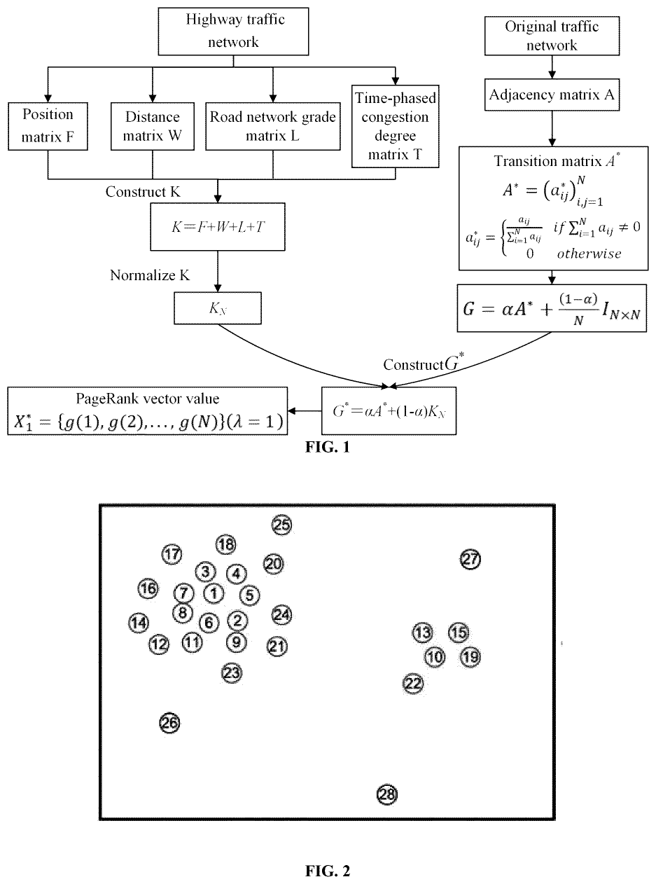

As shown in FIG. 1, the multi-scale aggregation pattern analysis method for the complex traffic network provided by the present disclosure includes the following steps S1-S3.

In S1, an adjacency matrix A, a position attribute matrix F, a distance weight matrix W, a road grade matrix L and a time-phased traffic congestion degree matrix T of the highway traffic network are calculated.

(1) The adjacency matrix A=(aᵢⱼ)_{N×N} is a square matrix of order N, and the element ay on the i-th row and the j-th column is defined as follows:

$${a}_{ij} = \{ \begin{matrix}{e}_{ij} , & i \neq j \\ 0 , & i = j\end{matrix} , 1 \leq i , j \leq N \qquad ( 1 - 1 )$$

If there is a road segment connection between a node i and a node j, then eᵢⱼ=1; otherwise, eᵢⱼ=0.

An example of part of the adjacency matrix A in this embodiment is shown in the following table (because the adjacency matrix of Langfang City, China is 16921 rows*16921 columns, it is not convenient to show here, so only part of the matrix A is provided):

TABLE 1
Example of part of the adjacency matrix
A of the highway traffic network

| | 1 | 2 | 3 | 4 |
|---|---|---|---|---|
| 1 | 0 | 0 | 1 | 1 |
| 2 | 0 | 0 | 0 | 0 |
| 3 | 1 | 0 | 0 | 1 |
| 4 | 1 | 0 | 1 | 0 |

Note: This example shows the connection of 4 nodes. If there is a road connection between node 1 and node 3, the value is 1; if there is no road connection between node 1 and node 2, the value is 0.

(2) The position attribute matrix F is constructed by using POI points to defined a 500-meter buffer zone and determining road segments in the highway network covered by the buffer zone so as to set position attribute values of the road segments. The weights of the road segments in the buffer zone are set to 1, while the weights of other road segments of the highway network are set to 0.

Assuming that vᵢ=1 (1≤i≤N) represents the position attribute of the road segment i according to a studied problem or an actual situation of the traffic network, and vᵢ=0 represents other situations. The position attribute matrix F is constructed as follows:

F=(v₁,v₂, . . . ,v_{N})_{1×N} (1-2)

TABLE 2
Example of part of the position attribute weighting matrix F

| | 1 | 2 | 3 | 4 |
|---|---|---|---|---|
| 1 | 0 | 0 | 0 | 0 |
| 2 | 0 | 0 | 1 | 0 |
| 3 | 0 | 1 | 0 | 0 |
| 4 | 0 | 0 | 0 | 0 |

Note: This example shows the position attribute weighting of the road network corresponding to four nodes. If there is a POI point on the road connecting node 2 and the node 3, the value is 1; if there is no POI point on the road connecting node 2 and node 3, the value is 0.

(3) In the distance weight matrix W=(wᵢⱼ)_{i,j=1}^{N}, wᵢⱼ represents a reciprocal of a shortest path length between node i and node j;

$${w}_{ij} = \{ \begin{matrix}\frac{1}{{d}_{ij}} ... . . i \neq j \\ 0 ... ... i = j\end{matrix} , 1 \leq i , j \leq N \qquad ( 1 - 3 )$$

where dᵢⱼ is the shortest path length between node i and node j in an initial traffic network structure, with a unit of km.

TABLE 3
Example of part of the distance weight matrix W

| | 1 | 2 | 3 | 4 |
|---|---|---|---|---|
| 1 | 0 | 0 | 0.99967 | 0.49405 |
| 2 | 0 | 0 | 0 | 0 |
| 3 | 0.99967 | 1 | 0 | 0.99928 |
| 4 | 0.494051 | 0 | 0.99928 | 0 |

Note: this example shows the distance weighting of the road network corresponding to four nodes. The reciprocal of the distance between node 1 and node 3 is calculated, and the weight obtained after unified normalization is 0.99967. There is no road connection between node 1 and node 2, that is, if the reciprocal of the distance value is close to 0, the weight is 0.

(4) In the road grade matrix L=(lᵢⱼ)_{i,j=1}^{N}, the element lᵢⱼ refers to a weight of the grade of a road between node i and node j. The higher the road grade is, the higher the weight is. The specific weight settings are shown in Table 4.

TABLE 4
Road grade weight distribution

| | | First- | Second- | Third- | Fourth- |
|---|---|---|---|---|---|
| | | class | class | class | class |
| Road | Motorway | highway | highway | highway | highway |
| Weight | 0.333 | 0.267 | 0.200 | 0.133 | 0.067 |

TABLE 5
Example of part of the road grade weight matrix L

| | 1 | 2 | 3 | 4 |
|---|---|---|---|---|
| 1 | 0 | 0 | 0.333 | 0.133 |
| 2 | 0 | 0 | 0 | 0 |
| 3 | 0.133 | 0 | 0 | 0.267 |
| 4 | 0.133 | 0 | 0.267 | 0 |

Note: as shown in Table 5, the example shows the road grade weighting of the road network corresponding to the four nodes. If the road connecting node 1 and the node 3 is the motorway, the value is 0.333; if there is no road connection between node 1 and node 2, the weight is 0.

(5) In the time-phased traffic congestion degree matrix T=(tᵢⱼ)_{i,j=1}^{N}, the element tᵢⱼ represents the weight of the traffic congestion degree between node i and node j, and the higher the congestion degree is, the larger the road weight is. The specific weight settings are shown in Table 6.

TABLE 6
Weight distribution of the road traffic congestion degree

| | | Mild | Moderate | Severe |
|---|---|---|---|---|
| grade of traffic | Clear | congestion | congestion | congestion |
| congestion degree | (IV) | (III) | (II) | (I) |
| Weight | 0.0875 | 0.1875 | 0.3125 | 0.4125 |

TABLE 7
Example of part of the time-phased
traffic congestion degree matrix T

| | 1 | 2 | 3 | 4 |
|---|---|---|---|---|
| 1 | 0 | 0 | 0.0875 | 0.3125 |
| 2 | 0 | 0 | 0 | 0 |
| 3 | 0.0875 | 0 | 0 | 0.1875 |
| 4 | 0.3125 | 0 | 0.1875 | 0 |

Note: the example shown in Table 7 shows the traffic congestion degree weighting of the road network corresponding to the four nodes. For example, if the road congestion between node 1 and node 3 is clear, the value is 0.0875; if there is no road connection between node 1 and node 2, the value is 0.

In S2, based on an original PageRank algorithm, a weight influence factor of the road network is added to obtain an improved PageRank algorithm, so as to determine order of critical nodes. The S2 specifically includes the follow steps.

(1) A Google matrix of PageRank, represented by G, is defined as:

$$G = α {A}^{*} + \frac{( 1 - α )}{N} {I}_{N \times N} \qquad ( 1 - 4 )$$

where A* is a transition matrix of the adjacency matrix A obtained from the original traffic network; α is a damping factor, and generally α=0.85. N represents a number of nodes in the traffic network (intersection points of roads in the highway traffic network), and I_{N×N} is a unit matrix of order N.

(2) A new weighting matrix K is defined by using the position attribute matrix F, the distance weight matrix W, the road grade matrix L and the time-phased traffic congestion degree matrix T:

K=F+W+L+T=(k₁,k₂, . . . ,kⱼ, . . . ,k_{N}) (1-5)

where kⱼ represents the j-th column of the matrix K.

TABLE 8
Example of part of the new weighting matrix K

| | 1 | 2 | 3 | 4 |
|---|---|---|---|---|
| 1 | 0 | 0 | 1.42017 | 0.93955 |
| 2 | 0 | 0 | 1 | 0 |
| 3 | 1.42017 | 1 | 0 | 1.45328 |
| 4 | 0.93955 | 0 | 1.45378 | 0 |

Note: the example shown in Table 8 shows the weighting of the road network corresponding to the four nodes. The weighted value of the road between node 1 and node 3 is 1.42017; the weighted value of the road between the node 1 and the node 2 is 0.

(3) Each column vector kⱼ of the matrix K is normalized to obtain a standard matrix K_{N}.

(4) A new matrix G* is constructed by replacing

$$\frac{( 1 - α )}{N} {I}_{N \times N}$$

with (1−α)K_{N}.

G*=αA*+(1−α)K_{N} (1-6)

According to Perron-Frobenius theorem, a main eigenvector X₁^{*}={g(1), g(2), . . . , g(N)}(λ=1) of G* is calculated by setting a eigenvalue of the eigenvector λ=1, to obtain grades of critical nodes; g(1), g(2), . . . , g(N) represent respective components of the main eigenvector X₁^{*}, and a value of a component indicates an importance degree of the node. The larger the value is, the more important the node is, which means that the node has a higher the criticality grade.

According to the Perron-Frobenius theorem (referring to Golub G H,Loan C F V.Matrixcomputation[M].Baltimore: The Johns Hopkins UniversityPress, 1996, 728(94):208-209 for details), the main eigenvector X₁^{*}={g(1), g(2), . . . , g(N)}(λ=1) of G* is calculated by setting the eigenvalue of the eigenvector λ=1, to obtain the grades of critical nodes; g(1), g(2), . . . , g(N) represent respective components of the main eigenvector X₁^{*}, and the value of the component indicates the importance degree of the node. The larger the value is, the more important the node is, which means that the node has a higher criticality grade.

In S3, a two-dimensional decision diagram is drawn by two indicators: order of critical nodes and a shortest path distance. Spectral clustering centers and a number k of clusters are determined. Based on a similarity matrix of spectral clustering algorithm, the position weight matrix, the distance weight matrix, the road grade weight matrix and dynamic traffic congestion degree weight matrix are added to obtain a new weighting matrix which accords with the actual situation of the road network. Then the clustering analysis is carried out to obtain aggregation blocks of the road network. Specific steps are as follows.

(1) The two-dimensional decision diagram is constructed to select the clustering center points and determine the number of clusters.

The paper (Stanfill C, WaltzD. Toward memory-based reasoning [J]. Communications of the ACM, 1986, 29 (12):1213-1228.) published by Alex Rodriguez and Alessandro Laio in science points out that the clustering center has the following two attributes:

1) The clustering centers are important nodes surrounded by low-impact neighbors; and

2) The initial cluster centers are evenly distributed in the physical network, and the “distance” between the centers is relatively large.

The present disclosure adopts a method of two-dimensional decision diagram to select the clustering center points. The number of the clustering center points is the number of clusters. The clustering center points are determined by considering ρ and δ, where ρ is the horizontal axis and δ is the vertical axis:

γᵢ=ρᵢδᵢ,i∈I_{S} (1-7)

where ρᵢ represents the i-th component of the main eigenvector X₁^{*}, and is used to evaluate the importance of node i; δᵢ represents the shortest path length between the node i and a more critical node, which is a critical node whose component value is greater than a predetermined threshold. Firstly, the path length between the node i and each critical node is calculated, and the shortest path length is δᵢ; I_{S} represents a set of nodes in an area S; a sequence of comprehensive values {γᵢ}ᵢ₌₁^{N} is calculated, where γᵢ=ρᵢδᵢ(i∈I_{S}) represents the comprehensive value of node i, and N represents the number of nodes. The larger the value of γ is, the more likely the node i is the clustering center. Therefore, it is desirable to sort {γᵢ}ᵢ₌₁^{N} in a descending order and then extract several data points from the front of the sorted {γᵢ}ᵢ₌₁^{N} to back as block centers. k nodes distributed on the upper right of the decision diagram are selected as the clustering centers, and k is a number of clusters.

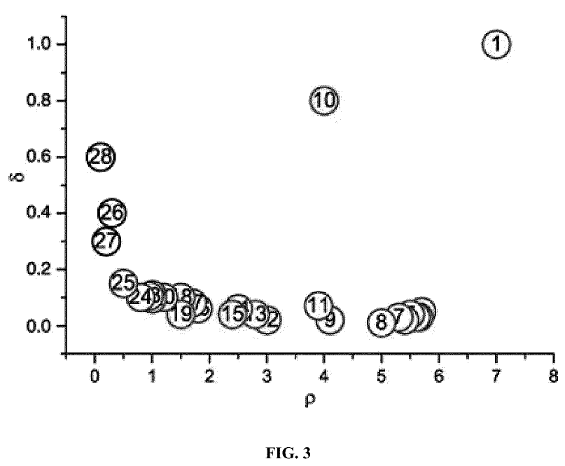

For example, the decision diagram is shown in FIG. 2 and FIG. 3. From FIG. 3, it can be seen that the No. 1 and No. 10 data points are larger in terms of both values of ρ and δ, and “pop up” from the data set. These two data points are just two clustering centers of the data set shown in FIG. 2.

(2) A weighting matrix is constructed, and the road network are divided into aggregation blocks by the spectral clustering algorithm. The specific steps are as follows.

There are n sample points X={x₁,x₂, . . . ,xₙ} and the number k of clusters.

1) A similarity matrix S={sᵢⱼ|1≤i≤n, 1≤j≤n} of n*n is calculated as follows:

$${S}_{ij} = {e}^{\frac{- {‖ {x}_{i} - {x}_{j} ‖}^{2}}{2 {σ}^{2}}} \qquad ( 1 - 8 )$$

where ∥xᵢ−xⱼ∥ represents a distance between two sample points, and the parameter σ defines a neighborhood width of a sample point, that is, the larger the σ is, the greater a similarity between the sample point and a farther sample point away from the sample point is, and vice versa.

TABLE 9
Example of part of the similarity matrix S

| | 1 | 2 | 3 | 4 |
|---|---|---|---|---|
| 1 | 0 | 1.18E−04 | 0.021049927 | 0.023497721 |
| 2 | 1.18E−04 | 0 | 0.021018653 | 0.023467179 |
| 3 | 0.021049927 | 0.021018653 | 0 | 0.002452333 |
| 4 | 0.023497721 | 0.023467179 | 0.002452333 | 0 |

Note: the example shown in Table 9 shows a similarity matrix consisting of four nodes. A similarity value between node 1 and node 3 is 0.021049927; a similarity value between node 1 and node 4 is 0.023497721.

2) Based on the similarity matrix S, combining with the position weight matrix F, the distance weight matrix W, the road grade weight matrix L and the dynamic traffic congestion degree weight matrix T, a new weighting matrix R which accords with the actual situation of the road network is obtained as follows:

R=S+F+W+L+T (1-9)

TABLE 10
Example of part of the weighting matrix R

| | 1 | 2 | 3 | 4 |
|---|---|---|---|---|
| 1 | 0 | 0.000117981 | 1.441219927 | 0.963047721 |
| 2 | 0.000117981 | 0 | 1.021018653 | 0.023467179 |
| 3 | 1.441219927 | 1.021018653 | 0 | 1.455732333 |
| 4 | 0.963047721 | 0.023467179 | 1.456232333 | 0 |

Note: the example shown in Table 10 shows part of the weighting matrix R. A weight between node 1 and node 3 is 1.441219927; a weight between node 1 and node 2 is 0.000117981.

3) A degree matrix D is calculated, where dᵢ=Σⱼ₌₁ⁿ rᵢⱼ is a sum of elements in each row of the weighting matrix R, and D is an n*n diagonal matrix composed of dᵢ.

4) A Laplace matrix L=D^{-1/2}LD^{-1/2}=D^{-1/2}(D−W)D^{-1/2} is calculated.

5) Eigenvalues of the Laplacian matrix L are calculated and sorted from small to large.

6) According to the two-dimensional decision diagram, the center nodes are selected to obtain the number k of clusters.

7) The first k eigenvalues of the Laplacian matrix L are selected and the eigenvectors u₁,u₂, . . . ,uₖ of the first k eigenvalues are calculated.

8) The eigenvectors of the first k eigenvalues are used to form a matrix U={u₁,u₂, . . . , uₖ}, U∈R^{n+k}.

9) yᵢ∈R^{k} is deemed to be a vector of the i-th row of U, where i=1,2, . . . ,n.

10) For i=1,2, . . . ,n, yᵢ∈R^{k} is sequentially unitized, so that |yᵢ|=1.

11) New sample points Y={y₁, y₂, . . . , yₙ} are grouped into clusters C₁,C₂, . . . ,Cₖ by using the k-means algorithm.

12) Clusters A₁,A₂, . . . ,Aₖ as a clustering result are obtained, where Aₖ={yᵢ|yᵢ∈Cₖ},i∈n.

In step S2, the expression of A* is as follows:

$${A}^{*} = {( {a}_{ij}^{*} )}_{i , j = 1}^{N} , \qquad ( 1 - 10 )$$

$${a}_{ij}^{*} = \{ \begin{matrix}\frac{{a}_{ij}}{{\sum }_{i = 1}^{N} {a}_{ij}} & if {\sum }_{i = 1}^{N} {a}_{ij} \neq 0 \\ 0 & otherwise\end{matrix} , \qquad ( 1 - 11 )$$

$$where :$$

$${a}_{ij} = \{ \begin{matrix}{e}_{ij} , & i \neq j \\ 0 , & i = j\end{matrix} , 1 \leq i , j \leq N , \qquad ( 1 - 12 )$$

when eᵢⱼ=1, it means that there is a road segment connection between node i and node j; when eᵢⱼ=0, it means the other case.

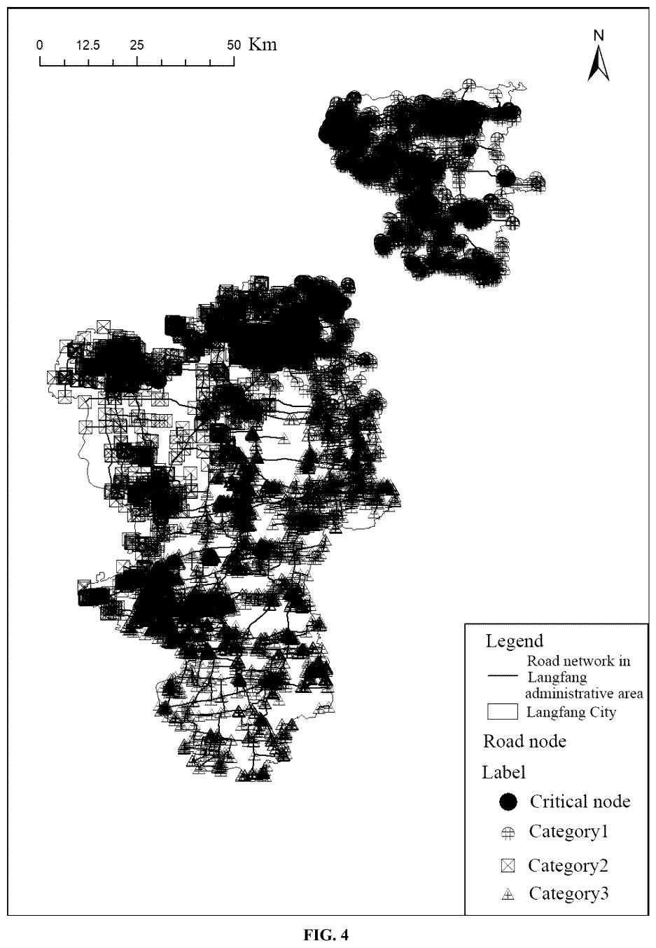

In the embodiments of the present disclosure, the multi-scale aggregation pattern analysis is performed by using two complex traffic networks in Langfang City, China and Xiong'an New Area, China as examples. FIG. 4 is a diagram of an application result of the multi-scale aggregation pattern analysis method for the complex traffic network to Langfang City, China as an example (due to the complex road network and huge amount of data in Langfang City, China, the key implementation data is given in the form of an attachment), which shows the block division results of the highway traffic network in Langfang City, China. The area formed by triangular intersections is Block 1; the area formed by circular intersections is Block 2; the area formed by rhombus intersections is Block 3. As shown in the block division result of FIG. 4, the road nodes in the block are more closely connected to each other. From FIG. 4, the center positions (black squares) of the three blocks can be readily found. From the perspective of geospatial structure, the highway traffic conditions in Langfang City, China can be effectively improved by improving the connectivity among and convenience of these three block structures. The routes connecting the center positions in the diagram are key routes. This figure provides a certain reference basis for relevant departments, showing the connectivity trend of highway traffic network. The location of the highway traffic network needed to be mainly maintained and improved can also be determined on the highway network connecting the block structures. By improving the connectivity of the centers, the connectivity of the overall highway traffic network in Langfang City, China can be improved, and operational efficiency of the highway traffic network can also be improved.

The existing analysis of the complex traffic network mostly stays at a single scale, and dynamic influence factors are not considered in the study of block aggregation characteristics of the highway traffic network, and the road network aggregation block division method mostly adopts the k-means clustering algorithm suitable for low-dimensional data, which results in a certain gap between the analysis results and the real situation. Based on the current situation, the present disclosure performs a multi-scale aggregation pattern analysis on a complex traffic network, and improves the road network aggregation block division method. For the problem that the dynamic influencing factors were not considered in the previous road network theoretical model, a road network theoretical model which incorporates the influence factors of position attribute weights, geographical distance weights, road grade weights, and dynamic time-phased traffic congestion degree weights is constructed. For the problem that the k-means algorithm is not effective in processing high-dimensional road network data, an improved spectral clustering algorithm is proposed for the road network aggregation block division. For the defects of the spectral clustering algorithm itself, an improved PageRank (APA) algorithm is proposed to obtain the order of the critical nodes in the highway traffic network; then the spectral clustering centers and the number of clusters are determined by two indicators, namely order of critical node and a shortest path distance; finally, the APA-spectral clustering algorithm is obtained, which can transcend the limitation of administrative division boundaries and obtain the division results of special common blocks in the highway traffic network; and the connectivity among blocks can improve the overall efficiency of the highway traffic network.

In this specification, some specific embodiments are used for illustration of the principles and implementations of the present disclosure. The description of the foregoing embodiments is used to help illustrate the method of the present disclosure and the core ideas thereof. In addition, those of ordinary skill in the art can make various modifications in terms of specific implementations and the scope of application in accordance with the ideas of the present disclosure. In conclusion, the content of this specification shall not be construed as limitations to the present disclosure.

What is claimed is:

1. A multi-scale aggregation pattern analysis method for a complex traffic network, comprising:
S1, calculating an adjacency matrix A, a position attribute matrix F, a distance weight matrix W, a road grade matrix L and a time-phased traffic congestion degree matrix T of a highway traffic network, wherein:
(1) the adjacency matrix A=(aᵢⱼ)_{N×N} is a square matrix of order N, and an element aᵢⱼ on a i-th row and a j-th column is defined as follows:
$${a}_{ij} = \{ \begin{matrix}{e}_{ij} , & i \neq j \\ 0 , & i = j\end{matrix} , 1 \leq i , j \leq N \qquad ( 1 - 1 )$$
if there is a road segment connection between a node i and a node j, eᵢⱼ=1; otherwise, eᵢⱼ=0;
(2) the position attribute matrix F is constructed by using POI points to define a 500-meter buffer zone, and determining road segments in the highway traffic network covered by the buffer zone so as to set position attribute values of the road segments, weights of road segments in the buffer zone are set to 1, and weights of other road segments of the highway traffic network are set to 0;
assuming that vᵢ=1 (1≤i≤N) represents a position attribute of a road segment i according to a studied problem or an actual situation of the highway traffic network, and vᵢ=0 represents other situations, the position attribute matrix F is constructed as follows:
F=(v₁,v₂, . . . ,v_{N})_{1×N} (1-2)
(3) the distance weight matrix W=(wᵢⱼ)_{i,j=1}^{N}, wᵢⱼ represents a reciprocal of a shortest path length between the node i and the node j;
$${w}_{ij} = \{ \begin{matrix}\frac{1}{{d}_{ij}} ... . . i \neq j \\ 0 ... ... i = j\end{matrix} , 1 \leq i , j \leq N \qquad ( 1 - 3 )$$
where dᵢⱼ is a shortest path length between the node i and the node j in an initial traffic network structure, with a unit of km;
(4) the road grade matrix L=(lᵢⱼ)_{i,j=1}^{N}, an element lᵢⱼ refers to a weight of a road grade between the node i and the node j, and as the road grade increases, the weight also increases;
(5) the time-phased traffic congestion degree matrix T=(tᵢⱼ)_{i,j=1}^{N}, an element tᵢⱼ represents a weight of a traffic congestion degree between the node i and the node j, and as the congestion degree increases, a road weight also increases;
S2, obtaining an improved PageRank algorithm by incorporating a weight influence factor based on an original PageRank algorithm, so as to determine order of critical nodes,where:
(1) a Google matrix of the PageRank, represented by G, is defined as:
$$G = α {A}^{*} + \frac{( 1 - α )}{N} {I}_{N \times N} \qquad ( 1 - 4 )$$
where A* is a transition matrix of the adjacency matrix A obtained from an original traffic network; α is a damping factor, generally α=0.85; N represents a number of nodes in the highway traffic network, and I_{N×N} is a unit matrix of order N;
(2) a new weighting matrix K is defined by using the position attribute matrix F, the distance weight matrix W, the road grade matrix L and the time-phased traffic congestion degree matrix T:
K=F+W+L+T=(k₁,k₂, . . . ,kⱼ, . . . ,k_{N}) (1-5)
where kⱼ represents a j-th column of the weighting matrix K;
(3) each column vector kⱼ of the weighting matrix K is normalized to obtain a standard matrix K_{N};
(4) a new matrix G* is constructed and obtained by replacing
$$\frac{( 1 - α )}{N} {I}_{N \times N}$$
with (1−α)K_{N}:
G*=αA*+(1−α)K_{N} (1-6)
according to Perron-Frobenius theorem, a main eigenvector X₁^{*}={g(1), g(2), . . . , g(N)}(λ=1) of G* is calculated by setting a eigenvalue of a eigenvector λ=1, to obtain grades of critical nodes; g(1), g(2), . . . , g(N) represent respective components of the main eigenvector X1^{*}, and a value of a component indicates an importance degree of a node, and as the value of the component increases, the importance degree of the node increases, and a criticality grade also increases;
S3, drawing a two-dimensional decision diagram by two indicators: order of critical nodes and a shortest path distance, to determine center points and a number k of clusters in a spectral clustering, obtaining a new weighting matrix which accords with an actual situation of the road network by incorporating a position weight matrix, a distance weight matrix, a road grade weight matrix and a dynamic traffic congestion degree weight matrix based on a similarity matrix of spectral clustering, and carrying out clustering analysis to obtain aggregation blocks of the road network.

2. The method according to claim 1, wherein in the S3, the drawing a two-dimensional decision diagram by two indicators: order of critical nodes and a shortest path distance, to determine center points and a number k of clusters in a spectral clustering, obtaining a new weighting matrix which accords with an actual situation of the road network by incorporating a position weight matrix, a distance weight matrix, a road grade weight matrix and a dynamic traffic congestion degree weight matrix based on a similarity matrix of spectral clustering, and carrying out clustering analysis to obtain aggregation blocks of the road network, comprises:
(1) constructing the two-dimensional decision diagram to select clustering center points and determine a number of clusters;
wherein a method of two-dimensional decision diagram is adopted to select the clustering centers, a number of the clustering center points is the number of clusters, the clustering center points are determined based on ρ and δ, wherein ρ is a horizontal axis and δ is a vertical axis:
γᵢ=ρᵢδᵢ,i∈I_{S} (1-7)
where ρᵢ represents a i-th component of the main eigenvector X₁^{*}, and is used to evaluate importance of the node i; δᵢ represents a shortest path length between the node i and a more critical node; I_{S} represents a set of nodes in an area S; a sequence of comprehensive values {γᵢ}ᵢ₌₁^{N} is calculated, where γᵢ=ρᵢδᵢ, i∈I_{S} represents a comprehensive value of the node i; as a reference value of γ increases, a possibly of the node i being a clustering center increases; therefore, {γᵢ}ᵢ₌₁^{N} are sorted in a descending order and a plurality of data points are extracted from the front of the sorted {γᵢ}ᵢ₌₁^{N} to back as block centers, k nodes distributed on upper right of the decision diagram are selected as clustering centers, and k is a number of clusters;
(2) constructing the weighting matrix, and dividing the road network into aggregation blocks by the spectral clustering, including:
for n sample points X={x₁,x₂, . . . ,xₙ} and a number k of clusters,
1) calculating a similarity matrix S={sᵢⱼ|1≤i≤n, 1≤j≤n} of n*n;
$${S}_{ij} = {e}^{\frac{- {‖ {x}_{i} - {x}_{j} ‖}^{2}}{2 {σ}^{2}}} \qquad ( 1 - 8 )$$
where ∥xᵢ−xⱼ∥ represents a distance between two sample points, and a parameter σ defines a neighborhood width of a sample point, as a value of the σ increases, a similarity between the sample point and a far sample point away from the sample point increases, and as a value of the σ decreases, the similarity between the sample point and the far sample point decreases;
2) obtaining a new weighting matrix R which accords with the actual situation of the road network by incorporating the position weight matrix F, the distance weight matrix W, the road grade weight matrix L and the dynamic traffic congestion degree weight matrix T based on the similarity matrix S;
R=S+F+W+L+T (1-9)
3) calculating a degree matrix D, where dᵢ=Σⱼ₌₁ⁿ rᵢⱼ is a sum of elements in each row of the weighting matrix R, and D is an n*n diagonal matrix composed of dᵢ;
4) calculating a Laplace matrix L=D^{-1/2}LD^{-1/2}=D^{-1/2}(D−W)D^{-1/2};
5) calculating eigenvalues of the Laplacian matrix L and sorting the eigenvalues from small to large;
6) selecting center nodes based on the two-dimensional decision diagram, and obtaining the number k of clusters;
7) calculating eigenvectors u₁,u₂, . . . ,uₖ of first k eigenvalues of the Laplacian matrix L by using the first k eigenvalues;
8) forming a matrix U={u₁,u₂, . . . ,uₖ},U∈R^{n+k} by using the eigenvectors of the first k eigenvalues;
9) letting yᵢ∈R^{k} be an eigenvector of a i-th row of U, where i=1,2, . . . ,n;
10) for i=1,2, . . . ,n, sequentially unitizing yᵢ∈R^{k}, so that |yᵢ|=1;
11) grouping new sample points Y={y₁,y₂, . . . ,yₙ} into clusters C₁,C₂, . . . ,Cₖ by using a k-means algorithm;
12) obtaining clustering result clusters A₁,A₂, . . . ,Aₖ, where Aₖ={yᵢ|yᵢ∈Cₖ}, i∈n.

3. The method according to claim 1, wherein in the step S2, an expression of A* is as follows:
$${A}^{*} = {( {a}_{ij}^{*} )}_{i , j = 1}^{N} , \qquad ( 1 - 10 )$$
$${a}_{ij}^{*} = \{ \begin{matrix}\frac{{a}_{ij}}{{\sum }_{i = 1}^{N} {a}_{ij}} & if {\sum }_{i = 1}^{N} {a}_{ij} \neq 0 \\ 0 & otherwise\end{matrix} , \qquad ( 1 - 11 )$$
$$wherein$$
$${a}_{ij} = \{ \begin{matrix}{e}_{ij} , & i \neq j \\ 0 , & i = j\end{matrix} , 1 \leq i , j \leq N , \qquad ( 1 - 12 )$$
when eᵢⱼ=1, it means that a road segment connection between the node i and the node j; when eᵢⱼ=0, it means other cases.
